(19) United States
(12) Patent Application Publication
(10) Pub. No.: US 2016/0065235 A1
(43) Pub. Date: Mar. 3, 2016

(54) CONTINUOUS ANALOG SIGNAL MONITORING

(71) Applicant: Qualcomm Incorporated, San Diego, CA (US)

(72) Inventors: Xiaohua KONG, San Diego, CA (US); Thuan LY, San Diego, CA (US); Behnam AMELIFARD, San Diego, CA (US); Ohjoon KWON, Irvine, CA (US)

(21) Appl. No.: 14/476,653

(22) Filed: Sep. 3, 2014

(51) Int. Cl. H03M 3/00

(52) U.S. Cl. CPC H03M 3/30

(57) ABSTRACT

An integrated circuit includes a first circuit configured to convert a digital signal of a first format, which includes a sampled version of an analog signal, to a digital signal of a second format. A second circuit is configured to output the digital signal of the second format through a digital interface. An electronic system including a circuit configured to output a digital signal of the analog signal as a bitstream is provided. A clock generator generates a clock for clocking the bitstream. In another aspect, a method for operating an integrated circuit includes converting a digital signal of a first format, which includes a sampled version of an analog signal, to a digital signal of a second format. The digital signal of the second format is outputted through a digital interface. A monitoring or observing device receives directly the digital signal of the second format through the digital interface.

### BACKGROUND

1. Field

The present disclosure relates generally to integrated circuits and electronic systems, and more particularly, to integrated circuits and electronic systems for real-time or continuous monitoring of analog signals.

2. Background

With the proliferation of wireless devices, more and more electronic systems and integrated circuits are implemented with mixed-signal circuits and functions. For example, a wireless device (e.g., a cellular phone or a smart phone) may transmit and receive data for two-way communication with a wireless communication system. The wireless device may include a transmitter for data transmission and a receiver for data reception. For data transmission, the transmitter may modulate a local oscillator (LO) signal with data to obtain a modulated radio frequency (RF) signal, amplify the modulated RF signal to obtain an output RF signal having the desired output power level, and transmit the output RF signal via an antenna to a remote device. For data reception, the receiver may obtain a received RF signal via the antenna, amplify and downconvert the received RF signal with an LO signal, and process the downconverted signal to recover data sent by the remote device.

Increasingly, the RF functions described above are been implemented with mixed-signal designs. For example, the analog signals may be converted to into the digital domain for processing, and vice versa. Traditional analog functions, such as a filter, may be implemented in digital circuit. Moreover, the tuning, compensation, and calibration of an analog circuit may likewise be performed in the digital domain.

On design challenge is to be able to monitor the analog signals in the mixed-signal designs in real time or continuously (e.g., observe or monitor the signal without a bus clocking delay).

### SUMMARY

Aspects of an integrated circuit are provided. The integrated circuit includes a first circuit configured to convert a digital signal of a first format, which includes a digital signal of an analog signal, to a digital signal of a second format. A second circuit is configured to output the digital signal of the second format through a digital interface.

Aspects of an electronic system are provided. The electronic system includes a circuit configured to output a continuous digital signal of the analog signal as a bitstream. A clock generator is configured to generate a clock for clocking the bitstream.

Aspects of a method for operating an integrated circuit are provided. The method includes converting a digital signal of a first format, which includes a digital signal of an analog signal, to a digital signal of a second format. The method further includes outputting the digital signal of the second format through a digital interface.

Aspects of an integrated circuit are provided. The integrated circuit includes means for converting a digital signal of a first format, which includes a sampled version of an analog signal, to a digital signal of a second format, and means for outputting the digital signal of the second format through a digital interface.

It is understood that other aspects of apparatus and methods will become readily apparent to those skilled in the art from the following detailed description, wherein various aspects of apparatus and methods are shown and described by way of illustration. As will be realized, these aspects may be implemented in other and different forms and its several details are capable of modification in various other respects. Accordingly, the drawings and detailed description are to be regarded as illustrative in nature and not as restrictive.

### BRIEF DESCRIPTION OF THE DRAWINGS

Various aspects of apparatus and methods will now be presented in the detailed description by way of example, and not by way of limitation, with reference to the accompanying drawings, wherein:

FIG. 1 is a block diagram of an exemplary SerDes interface.

FIG. 2 is a block diagram of an exemplary electronic system for monitoring an analog signal.

FIG. 3 is a flowchart of operations of an exemplary electronic system for monitoring an analog signal.

### DETAILED DESCRIPTION

The detailed description set forth below in connection with the appended drawings is intended as a description of various exemplary embodiments of the present invention and is not intended to represent the only embodiments in which the present invention may be practiced. The detailed description includes specific details for the purpose of providing a thorough understanding of the present invention. However, it will be apparent to those skilled in the art that the present invention may be practiced without these specific details. In some instances, well-known structures and components are shown in block diagram form in order to avoid obscuring the concepts of the present invention. Acronyms and other descriptive terminology may be used merely for convenience and clarity and are not intended to limit the scope of the invention.

Various apparatus and methods presented throughout this disclosure may be implemented in various forms of hardware. By way of example, any of these apparatus or methods, either alone or in combination, may be implemented as an integrated circuit, or as part of an integrated circuit. The integrated circuit may be an end product, such as a microprocessor, a digital signal processor (DSP), an application specific integrated circuit (ASIC), programmable logic, or any other suitable integrated circuit. Alternatively, the integrated circuit may be integrated with other chips, discrete circuit elements, and/or other components as part of either an intermediate product, such as a motherboard, or an end product. The end product can be any suitable product that includes integrated circuits, including by way of example, a cellular phone, personal digital assistant (PDA), laptop computer, a desktop computer (PC), a computer peripheral device, a multimedia device, a video device, an audio device, a global positioning system (GPS), a wireless sensor, or any other suitable device.

The word “exemplary” is used herein to mean serving as an example, instance, or illustration. Any embodiment described herein as “exemplary” is not necessarily to be construed as preferred or advantageous over other embodiments. Likewise, the term “embodiment” of an apparatus or method does not require that all embodiments of the invention include the described components, structure, features, functionality, processes, advantages, benefits, or modes of operation.

When a “signal” is reference, the term may include the conductor carrying the described signal. The term “connection” may include a signal line. The terms “connected,” “coupled,” or any variant thereof, mean any connection or coupling, either direct or indirect, between two or more elements, and can encompass the presence of one or more intermediate elements between two elements that are “connected” or “coupled” together. The coupling or connection between the elements can be physical, logical, or a combination thereof. As used herein, two elements can be considered to be “connected” or “coupled” together by the use of one or more wires, cables and/or printed electrical connections, as well as by the use of electromagnetic energy, such as electromagnetic energy having wavelengths in the radio frequency region, the microwave region and the optical (both visible and invisible) region, as several non-limiting and non-exhaustive examples.

Any reference to an element herein using a designation such as “first,” “second,” and so forth does not generally limit the quantity or order of those elements. Rather, these designations are used herein as a convenient method of distinguishing between two or more elements or instances of an element. Thus, a reference to first and second elements does not mean that only two elements can be employed, or that the first element must precede the second element.

As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of the stated features, integers, steps, operations, elements, and/or components, but do not preclude the presence or addition of one or more other features, integers, steps, operations, elements, components, and/or groups thereof

Various aspects of electronic systems and integrated circuits for real-time or continuous monitoring of an analog signal are provided. As those skilled in the art will readily appreciate, aspects and applications of the disclosure may not be limited to the described exemplary embodiments. Accordingly, all references to a specific application are intended only to illustrate exemplary aspects of the electronic systems and integrated circuits with the understanding that such aspects may have a wide differential of applications.

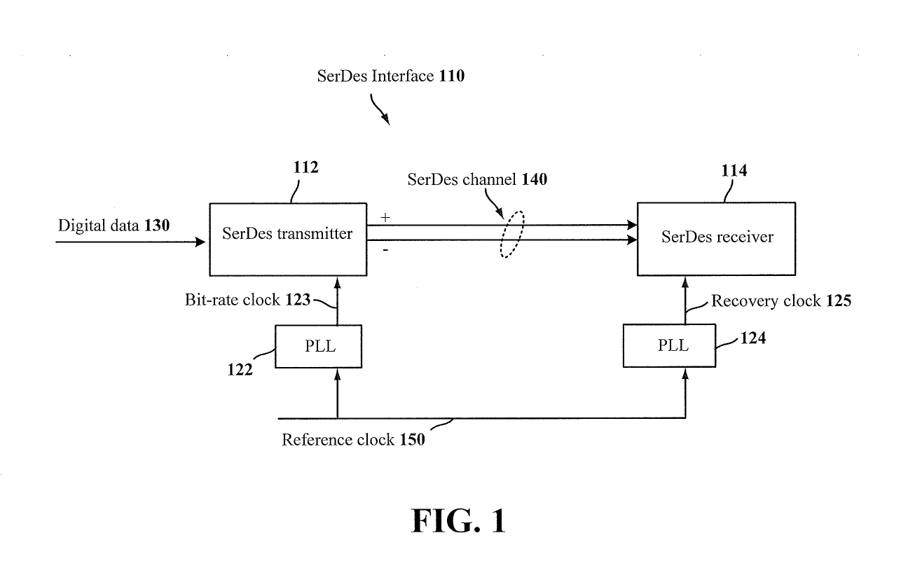

FIG. 1 is a block diagram of an exemplary SerDes interface. The SerDes 110 may also be known as a serializer/deserializer. In one example, a SerDes transmitter 112 receives digital data 130 and transmits the data as a bitstream over the SerDes channel 140. For example, a bitstream is a series of bits, and the series of bits, representing the digital data, is transmitted serially over the SerDes channel 140. In one implementation, the SerDes channel 140 includes a pair of transmission lines (positive and negative ends of a differential signal) for transmitting the bitstream as differential signals.

At the transmission end, the bitstream transmission is synchronized with or clocked by the bit-rate clock 123. In one implementation, the bit-rate clock 123 is generated using a clock generator, such as a phase-locked loop (PLL) 122, based on a reference clock 150. For example, the PLL 122 may generate the bit-rate clock 123 at a frequency M times the frequency of the reference clock 150.

At a receiving end, the SerDes receiver 114 receives the bitstream on the SerDes channel 140. The recovery clock PLL 124 receives the reference clock 150 and generates the recovery clock 125. For example, the recovery clock PLL 124 may generate the recovery clock 125 at a frequency M times the frequency of the reference clock 150. In one implementation, the recovery clock 125 may run at a same frequency as the bit-rate clock 123, allowing the SerDes receiver 114 to synchronize with the received bitstream and recover the data from the received bitstream.

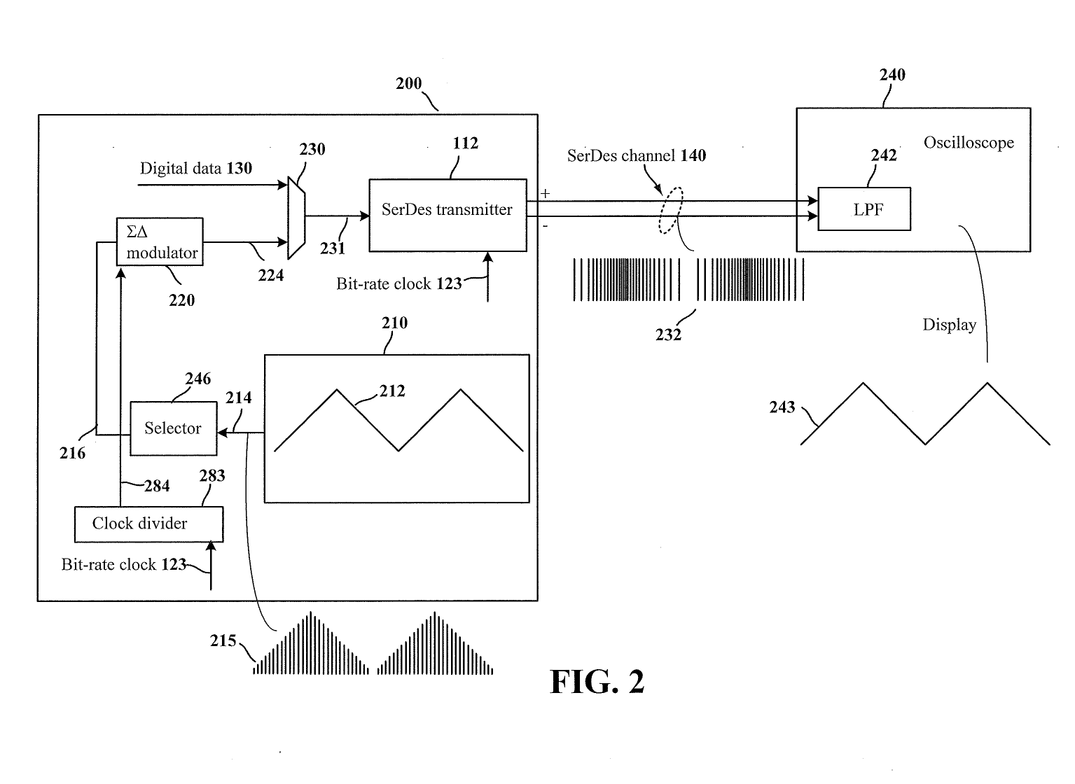

FIG. 2 is a block diagram of an exemplary electronic system for monitoring an analog signal. A semiconductor device 200, e.g., a processor for a wireless device, includes various integrated circuits described below. A mixed-signal circuit 210 generates an analog signal 212 and a digital signal 215, which may be a digital, sampled version of the analog signal 212. In one example, to observe or monitor the analog signal 212, the signal may be outputted (e.g., directly connected) to a monitor pin of the semiconductor device 200. However, such a scheme requires a dedicated pin for monitoring purposes. In another example, a sampled version of the analog signal 212 (e.g., the digital signal 215) may be outputted via a digital bus. However, in this scheme, the output is clocked by a bus clock and therefore, is subjected to the bus clocking delays. For example, the digital signal 215 may be put onto the digital bus and outputted by the digital bus, which is clocked by the digital bus clock. As is known in the art, such a scheme conveys no real-timing information as the digital values are outputted in accordance with the digital bus clock. In other words, such a scheme does not output, for observation or monitoring, a real-time digital signal or a continuous digital signal of the analog signal 212.

In FIG. 2, the mixed-signal circuit 210 outputs to a signal line 214, which carries the digital signal 215 (e.g., a sampled version of the analog signal 212). In one example, the analog signal 212 is sampled at various times. The sampled voltages are quantized into digital values. Thus, the digital signal 215 may include the voltages of samples of the analog signal 212. An example of the sampled version of the analog signal 212 is shown as the digital signal 215 in FIG. 2. A selector 246 receives from the signal line 214 the digital signal 215 and selects a subset of bits therefrom (the selected bits remain a digital signal and a sampled version of the analog signal 212). The selector 246 outputs to signal line 216 the selected bits of the digital signal 215 to a sigma-delta modulator 220. In one implementation, this feature allows for the selection of the different granularity of the digital signal 215 (the sampled version of the analog signal 212) for output (e.g., by the SerDes transmitter 112). For example, the selector 246 may selects bits that correspond to the most significant bits or the least significant bits of the digital signal 215.

The sigma-delta modulator 220 receives the input from the signal line 216 and converts it into a different digital format (e.g., a series or sequence of bits or a bitstream format). Thus, the signal line 224 also carries a digital signal that includes a sampled version of the analog signal 212, but in a different format. In one implementation, the clock divider 283 divides the bit-rate clock 123 and outputs the divided clock 284. The clock divider 283 provides the divided clock 284 to the sigma-delta modulator 220 to perform the conversion of the digital signal 215 (or the selected bits thereof) via the signal line 216. The sigma-delta modulator 220 outputs to a multiplexer 230 via the signal line 224. As presented above, the signal line 224 carries a digital signal of a different format (e.g., a series or sequence of bits or a bitstream format) from the sigma-delta modulator 220.

The multiplexer 230 selects between the digital signal at the signal line 224 and digital data 130. In one implementation, digital data 130 arise from the digital domain operation of the semiconductor device 200, and therefore, digital data 130 may be digital signals having no corresponding analog signals generated. For example, no analog signals are generated in the semiconductor device 200 that correspond to the digital data 130. In one implementation, the multiplexer 230 selects the digital signal at the signal line 224 and outputs on signal line 231, which is inputted to the SerDes transmitter 112. As described with FIG. 1, the SerDes transmitter 112 outputs a digital signal 232 through the digital SerDes interface. For example, the SerDes transmitter 112 outputs the digital signal 232 via the SerDes channel 140 as a bitstream (e.g., clocked by the bit-rate clock 123 as described in FIG. 1). Thus, the digital signal 232 is of a different format from the digital signal 215.

As described above, the SerDes transmitter 112 outputs the digital signal 232 in the bitstream format (which is converted from the digital signal 215 or the sampled version of the analog signal 212) continuously and in real-time. The output path from the analog signal 212 to the digital signal 232 on the SerDes channel 140 may bypass any and all digital buses, and therefore, the digital signal 232 in the bitstream format (which is converted from the digital signal 215 or the sampled version of the analog signal 212) outputted by the SerDes transmitter 112 is not subjected to the bus clocks. Moreover, the SerDes interface typically operates a high frequency (e.g., in the gigahertz range). Thus, in one implantation, the digital signal 232 is transmitted at a higher frequency than the digital signal 215.

In one implementation, the digital signal 232 transmitted on the SerDes channel 140 is received by a monitoring device, such as an oscilloscope 240. In this example, the monitoring device is outside of the semiconductor device 200, but the scope of the disclosure is not limited thereto. In one example, the oscilloscope 240 receives the digital signal 232 directly. In one example, the oscilloscope 240 includes a low-pass filter 242, and therefore, no additional low-pass filter external to the oscilloscope 240 is needed. Moreover, unlike the SerDes receiver 114, the oscilloscope 240 receives the digital signal 232 on the SerDes channel 140 without receiving or using a recovery clock. In one implementation, the low-pass filter 242 recovers a representation of the analog signal 212, which is shown at 243. The oscilloscope 240 displays the representation 243 of the analog signal 212, allowing the analog signal 212 to be monitored.

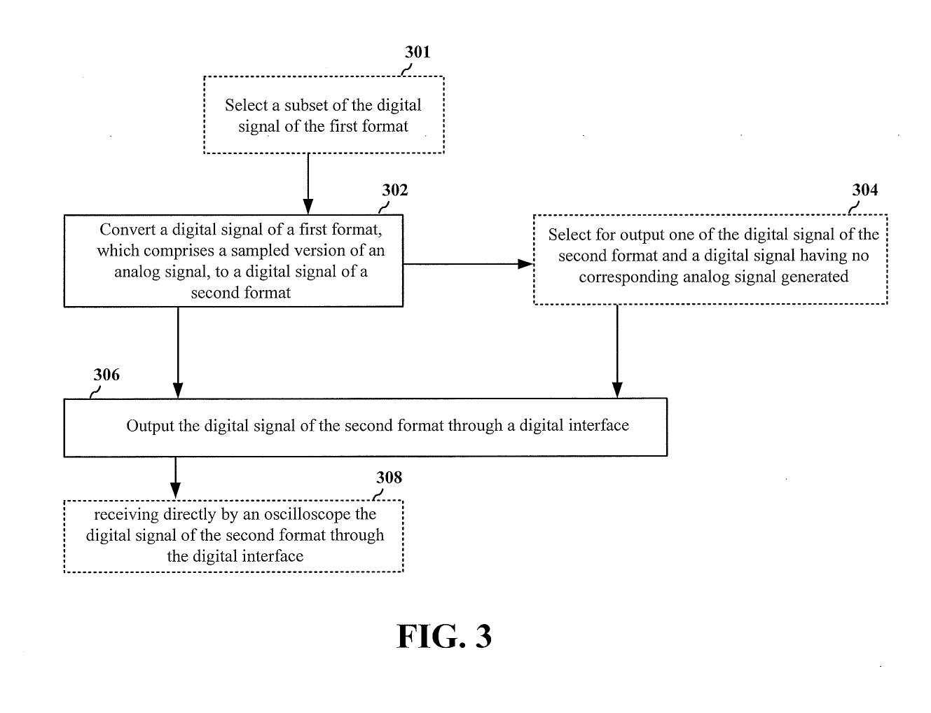

FIG. 3 is a flowchart of operations of an exemplary electronic system for monitoring an analog signal. The steps drawn in dotted lines may be optional. At 301, a subset of a digital signal of the first format is selected. For example, a digital signal may be in the format of a digital representation of sampled voltages of the analog signal 212. The selector 246 provides the means to select a subset of the digital signal 215 at signal line 214. At 302, a digital signal of a first format, which comprises a sampled version of an analog signal, is converted to a digital signal of a second format. For example, the digital signal 215 may include a sampled version of the analog signal 212. The sigma-delta modulator 220 converts the digital signal 215 to the digital signal of a second format (e.g., a series or sequence of bits; a bitstream). In one example, the sigma-delta modulator 220 converts the digital signal 215 by converting the selected subset of the digital signal at signal line 216 (outputted by the selector 246). In one implementation, the sigma-delta modulator 220 provides the means for converting a digital signal of a first format (e.g., digital signal 215), which comprises a sampled version of an analog signal (e.g., 212), to a digital signal of a second format (e.g., the digital signal outputted at signal line 224 as a series or sequence of bits).

At 304, one of the digital signal of the second format and a digital signal having no corresponding analog signal generated is selected for output. For example, the multiplexer 230 selects from one of the digital signal of the second format (e.g., the digital signal outputted at signal line 224 as a series or sequence of bits) and the digital signal having no corresponding analog signal generated (e.g., digital data 130) for output (e.g., outputted by the SerDes transmitter 112). In one implementation, the multiplexer 230 provides the means for selecting for output one of the digital signal of the second format (e.g., the digital signal outputted at signal line 224 as a series or sequence of bits) and a digital signal having no corresponding analog signal generated (e.g., digital data 130). For example, no analog signals are generated in the semiconductor device 200 that correspond to the digital data 130.

At 306, the digital signal of the second format is outputted through a digital interface. For example, the SerDes transmitter 112 outputs the digital signal of the second format (e.g., the digital signal on the signal line 224 in the bitstream format). In one implementation, the SerDes transmitter 112 provides the means to output the digital signal of the second format. At 308, a monitoring device directly receives the digital signal of the second format through the digital interface. For example, the oscilloscope 240 directly receives the digital signal of the second format (e.g., the digital signal on the signal line 224 in the bitstream format) through the digital interface (e.g., the SerDes transmitter 112). In one implementation, the oscilloscope 240 provides the receiving means for directly receiving the digital signal of the second format (e.g., the digital signal on the signal line 224 in the bitstream format) through the digital interface (e.g., the SerDes transmitter 112). Further examples of these operations are described in association with FIGS. 1-2.

The specific order or hierarchy of blocks in the method of operation described above is provided merely as an example. Based upon design preferences, the specific order or hierarchy of blocks in the method of operation may be re-arranged, amended, and/or modified. The accompanying method claims include various limitations related to a method of operation, but the recited limitations are not meant to be limited in any way by the specific order or hierarchy unless expressly stated in the claims.

The various aspects of this disclosure are provided to enable one of ordinary skill in the art to practice the present invention. Various modifications to exemplary embodiments presented throughout this disclosure will be readily apparent to those skilled in the art, and the concepts disclosed herein may be extended to other magnetic storage devices. Thus, the claims are not intended to be limited to the various aspects of this disclosure, but are to be accorded the full scope consistent with the language of the claims. All structural and functional equivalents to the various components of the exemplary embodiments described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed under the provisions of 35 U.S.C. §112(f) unless the element is expressly recited using the phrase “means for” or, in the case of a method claim, the element is recited using the phrase “step for.”

What is claimed is:

1. An integrated circuit, comprising:
a first circuit configured to convert a digital signal of a first format, which comprises a sampled version of an analog signal, to a digital signal of a second format; and
a second circuit configured to output the digital signal of the second format through a digital interface.

2. The integrated circuit of claim 1, wherein the outputted digital signal of the second format comprises a continuous digital signal of the analog signal.

3. The integrated circuit of claim 2, wherein the digital signal of the first format comprises a digital representation of voltages of samples of the analog signal.

4. The integrated circuit of claim 2, wherein the second circuit is configure to output the digital signal of the second format as a bitstream.

5. The integrated circuit of claim 4, wherein the second circuit is configured to selectively output a digital signal having no corresponding analog signal generated on the integrated circuit.

6. The integrated circuit of claim 5, wherein the bitstream operates at a higher frequency than the digital signal of the first format.

7. The integrated circuit of claim 2, further comprising a third circuit configured to select a subset of the digital signal of the first format, wherein the first circuit is configured to convert the digital signal of the first format to the digital signal of the second format by converting the subset of the digital signal of the first format.

8. The integrated circuit of claim 1, wherein the digital interface comprises a SerDes interface.

9. The integrated circuit of claim 1, wherein the first circuit comprises a sigma-delta modulator.

10. A method for operating an integrated circuit, comprising:
converting a digital signal of a first format, which comprises a sampled version of an analog signal, to a digital signal of a second format; and
outputting the digital signal of the second format through a digital interface.

11. The method of claim 10, wherein the outputted digital signal of the second format comprises a continuous representation of the analog signal.

12. The method of claim 11, wherein the digital signal of the first format comprises a digital representation of voltages of samples of the analog signal.

13. The method of claim 11, wherein the digital signal of the second format is outputted as a bitstream.

14. The method of claim 13, further comprising selecting for output one of the digital signal of the second format and a digital signal having no corresponding analog signal generated.

15. The method of claim 14, wherein the bitstream operates at a higher frequency than the digital signal of the first format.

16. The method of claim 11, further comprising selecting a subset of the digital signal of the first format, wherein the converting the digital signal of the first format to the digital signal of the second format comprises converting the subset of the digital signal of the first format.

17. The method of claim 11, further comprising receiving directly by a monitoring device the digital signal of the second format through the digital interface.

18. The method of claim 10, wherein the digital interface comprises a SerDes interface.

19. The method of claim 10, wherein the converting to the second format comprises a sigma-delta modulation.

20. An electronic system, comprising:
a circuit configured to output a continuous digital signal of an analog signal as a bitstream; and
a clock generator configured to generate a clock for clocking the bitstream.

21. The electronic system of claim 20, further comprising a monitoring device configured to receive the bitstream.

22. The electronic system of claim 21, wherein the monitoring device is configured to receive the bitstream without receiving a second clock.

23. The electronic system of claim 21, wherein the monitoring device is configured to receive the bitstream directly.

24. The electronic system of claim 21, wherein the monitoring device is configured to display a representation of the analog signal.

25. The electronic system of claim 20, wherein the circuit comprises a SerDes transmitter.

26. An integrated circuit, comprising:
means for converting a digital signal of a first format, which comprises a sampled version of an analog signal, to a digital signal of a second format; and
means for outputting the digital signal of the second format through a digital interface.

27. The integrated circuit of claim 26, wherein the outputted digital signal of the second format comprises a continuous representation of the analog signal.

28. The integrated circuit of claim 26, further comprising means for selecting a subset of the digital signal of the first format, wherein the means for converting the digital signal of the first format to the digital signal of the second format is configured to convert the subset of the digital signal of the first format.

29. The integrated circuit of claim 26, further comprising means for selecting for output one of the digital signal of the second format and a digital signal having no corresponding analog signal generated.

30. The integrated circuit of claim 26, wherein the digital interface comprises a SerDes interface.
